(19) United States
(12) Patent Application Publication
(10) Pub. No.: US 2019/0198296 A1
(43) Pub. Date: Jun. 27, 2019

(54) Plasma Processing Apparatus and Method of Manufacturing Semiconductor Device Using the Same

(71) Applicant: Samsung Electronics Co., Ltd., Suwon-si (KR)

(72) Inventors: SIQING LU, Seongnam-si (KR); YEONGKWANG LEE, Suwon-si (KR); KEESOO PARK, Hwaseong-si (KR); SEUNGJAE LEE, Hwaseong-si (KR); JINHYUK CHOI, Suwon-si (KR)

(21) Appl. No.: 16/104,496

(22) Filed: Aug. 17, 2018

(30) Foreign Application Priority Data
Dec. 27, 2017 (KR) 10-2017-0181247

(51) Int. Cl. H01J 37/32; H01L 21/67

(52) U.S. Cl. CPC H01J 37/3222; H01J 37/32229; H01J 37/32449; H01J 37/32238; H01J 2237/3341; H01J 37/32834; H01J 37/32513; H01L 21/67011; H01J 37/32201

(57) ABSTRACT

Disclosed are plasma processing apparatuses and methods of manufacturing semiconductor devices. The plasma processing apparatus includes a chamber including lower and upper housings, a window in the upper housing, an antenna for generating plasma of a first gas, wherein the antenna is disposed on the window and in the upper housing, a first pump for exhausting the first gas between the window and the lower housing, wherein the first pump is associated with the lower housing, a power supply for providing a power output, wherein the power supply is connected to the antenna through a first cavity of the upper housing, and a second pump for pumping a second gas between the window and in the upper housing so as to hold the antenna and the window onto an inside wall of the upper housing.

### CROSS-REFERENCE TO RELATED APPLICATION

This U.S. non-provisional application claims priority under 35 U.S.C. § 119 to Korean Patent Application No. 10-2017-0181247 filed on Dec. 27, 2017, in the Korean Intellectual Property Office, the entire contents of which are hereby incorporated by reference.

### BACKGROUND

Inventive concepts relate to apparatus and method of manufacturing a semiconductor device, and more particularly, to a plasma processing apparatus and a method of manufacturing a semiconductor device using the same.

In general, a plurality of unit processes may be performed to manufacture a semiconductor device. The unit processes may include a deposition process, a diffusion process, a thermal process, a photolithography process, a polishing process, an etching process, an ion implantation process, a cleaning process, and the like. The etching process may include a dry etching process and a wet etching process. A plasma reaction may be used to perform the deposition process and the dry etching process.

### SUMMARY

Some embodiments of inventive concepts provide a plasma processing apparatus capable of minimizing window deformation.

Some embodiments of inventive concepts provide a plasma processing apparatus capable of minimizing power delivery loss.

According to exemplary embodiments of inventive concepts, a plasma processing apparatus may include: a chamber including a lower housing and an upper housing on the lower housing; a window in the upper housing; an antenna for generating a plasma of a first gas, wherein the antenna is disposed on the window and in the upper housing; a first pump for exhausting the first gas between the window and the lower housing, wherein the first pump is associated with the lower housing; a power supply for providing a power output, wherein the power supply is connected with the antenna through a first cavity of the upper housing; and a second pump for pumping a second gas between the window and the upper housing so as to hold the antenna and the window onto an inside wall of the upper housing, wherein the second pump is associated with a second cavity of the upper housing, wherein the second cavity is different from the first cavity, and wherein second pump is associated independently of the power supply.

According to exemplary embodiments of inventive concepts, a plasma processing apparatus may include: a chamber; a window in the chamber; an antenna for generating plasma, wherein the antenna is disposed on the window and in the chamber; and a power supply for delivering power to the antenna, wherein the power supply includes a power feed, wherein the power feed passes through the antenna and extends to the window and wherein the window may have a central groove receiving an end of the power feed.

According to exemplary embodiments of inventive concepts, a method of manufacturing a semiconductor device may include: providing a substrate into a lower housing of a chamber; and processing the substrate using microwave power output provided through an antenna and a window that are in an upper housing on the lower housing. The step of processing the substrate may include: pumping a first gas between the lower housing and the window; pumping a second gas on the window and in the upper housing; and generating plasma of the first gas by providing the antenna with the microwave from a power supply. The step of pumping the second gas may include exhausting the second gas independently of the power supply.

### BRIEF DESCRIPTION OF THE DRAWINGS

FIG. 1 illustrates a schematic diagram showing a plasma processing apparatus according to exemplary embodiments of inventive concepts.

FIG. 2 illustrates a cross-sectional view showing an example of a power feed and a connection part in section A of FIG. 1.

FIG. 3 illustrates a perspective view showing an example of a lower connection part of FIG. 2.

FIG. 4 illustrates a flow chart showing a method of manufacturing a semiconductor device, according to exemplary embodiments of inventive concepts.

FIG. 5 illustrates a flow chart showing an example of a substrate processing step of FIG. 4.

### DETAILED DESCRIPTION OF EMBODIMENTS

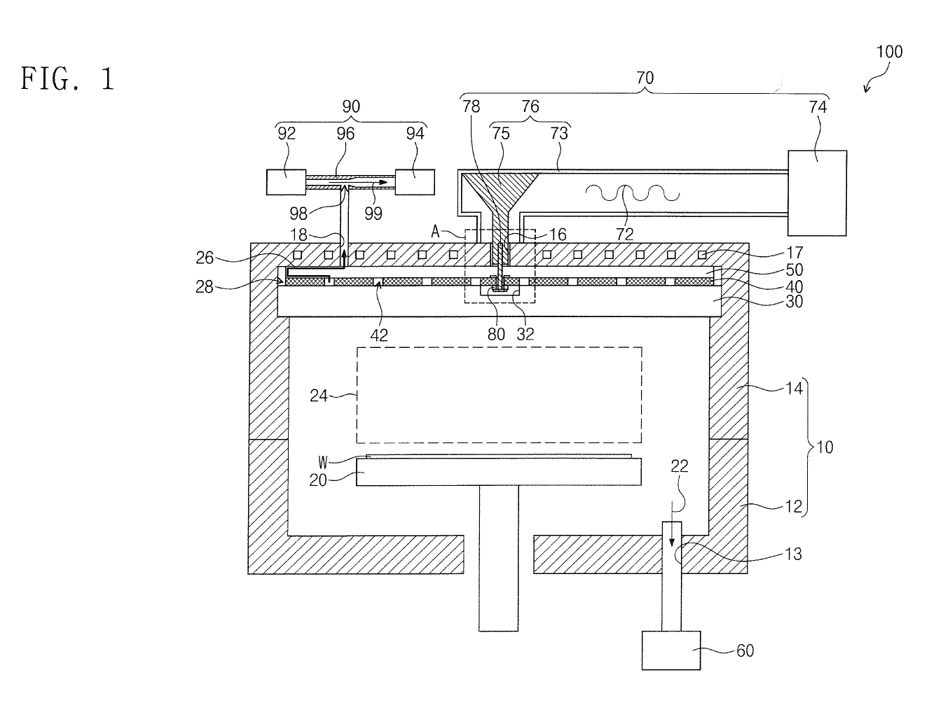

FIG. 1 shows a plasma processing apparatus 100 according to exemplary embodiments of the inventive concepts.

Referring to FIG. 1, the plasma processing apparatus 100 of the inventive concepts may be a substrate etching apparatus or a thin-layer deposition apparatus. Alternatively, the plasma processing apparatus 100 may be an ion implantation apparatus. In an embodiment, the plasma processing apparatus 100 may include a chamber 10, a chuck 20, a dielectric window 30, an antenna 40, a dielectric plate 50, a first pump 60, a power supply 70; a connection part 80, and a second pump 90.

The chamber 10 may provide a substrate W in a space hermetically sealed from the outside. In an embodiment, the chamber 10 may include a lower housing 12 and an upper housing 14. The lower housing 12 may accommodate the chuck 20. For example, the lower housing 12 may include an aluminum alloy. The upper housing 14 may be disposed on the lower housing 12. When the lower housing 12 is separated from the upper housing 14, the substrate W may be loaded into the chamber 10. The substrate W may also be unloaded from the chamber 10. When the lower housing 12 and the upper housing 14 are combined with each other, the substrate W may be processed with a plasma 24. For example, the substrate W may be etched or a thin layer deposited thereon.

The chuck 20 may be installed in the lower housing 12. The substrate W may be held on the chuck 20. The chuck 20 may fix and/or heat up the substrate W. For example, the chuck 20 may include an electrostatic chuck, a heater, or a susceptor.

The dielectric window 30 may be disposed in the upper housing 14. The dielectric window 30 may separate and/or insulate the antenna 40 from the plasma 24 generated on the substrate W. For example, the dielectric window 30 may include a disc of quartz (e.g., SiO₂).

The antenna 40 may be disposed on the dielectric window 30. The antenna 40 may be installed in the upper housing 14. The antenna 40 may have a sidewall spaced apart from an inner wall of the upper housing 14. A first gas 22 may be converted into the plasma 24 beneath the dielectric window 30 when the antenna 40 is provided with a microwave power output 72. The antenna 40 may include a metal plate (e.g., Cu, Ni, or Au). In an embodiment, the antenna 40 may include a plurality of slots 42. The microwave power output 72 may be irradiated through the slots 42 onto the dielectric window 30. The microwave power output 72 may induce formation of the plasma 24 of the first gas 22 between the dielectric window 30 and the lower housing 12.

The dielectric plate 50 may be disposed on the antenna 40. The dielectric plate 50 may insulate the antenna 40 from the upper housing 14. The dielectric plate 50 may include a disc of quartz (e.g., SiO₂). In an embodiment, the dielectric plate 50 may have the same diameter as that of the antenna 40. The diameter of the dielectric plate 50 may be smaller than that of the dielectric window 30. The dielectric plate 50 and the antenna 40 may each have a sidewall spaced apart from an inside wall of the upper housing 14. For example, the sidewalls of the antenna 40 and the dielectric plate 50 may be spaced apart at a predetermined gap 28 from the inside wall of the upper housing 14.

The first pump 60 may be associated with the lower housing 12. When the lower housing 12 and the upper housing 14 are combined with each other, the first pump 60 may exhaust the first gas 22 through a lower cavity 13 of the lower housing 12. The first gas 22 may include an etching gas or a deposition gas. When the first pump 60 pumps the first gas 22, the first gas 22 may have a pressure ranging from about 1 mTorr to about 1 Torr in the chamber 10. For example, the first pump 60 may include a dry pump (e.g., rotary pump, screw pump, or turbo pump).

The power supply 70 may supply the antenna 40 with the microwave power output 72. When the first gas 22 is exhausted and/or pumped, the antenna 40 may be provided with the microwave power output 72. In an embodiment, the power supply 70 may include a power source 74, a waveguide 76, and a power feed 78.

The power source 74 may use electrical power to produce the microwave power output 72. For example, the power source 74 may produce the microwave power output 72 ranging from about 100 W to about 1 MW. The microwave power output 72 may generate the plasma 24 at frequency less than that of a radio frequency power output. A damage rate of the substrate W may be proportional to frequency and/or magnitude of power. In an etching process, the substrate W may be less damaged from the microwave power output 72 than that of a radio frequency power output.

The waveguide 76 may couple the power source 74 to the upper housing 14. The microwave power output 72 may be provided along the waveguide 76 into the upper housing 14. In an embodiment, the waveguide 76 may include an outer waveguide 73 and an inner waveguide 75. The outer waveguide 73 may couple the power source 74 onto a center of the upper housing 14. For example, the outer waveguide 73 may include a metal tube. The microwave power output 72 may be provided into the inner waveguide 75 along air (e.g., N₂) in the outer waveguide 73 and along an inner wall of the outer waveguide 73. The inner waveguide 75 may be installed within the outer waveguide 73 on a center of the dielectric plate 50. The inner waveguide 75 may be inserted into a first upper cavity 16 of the upper housing 14. For example, the inner waveguide 75 may have a screw shape. The inner waveguide 75 may include metal (e.g., Cu, Ni, or Au). In an embodiment, the inner waveguide 75 may receive the microwave power output 72 in the outer waveguide 73, and provide the power feed 78 with the received microwave power output 72.

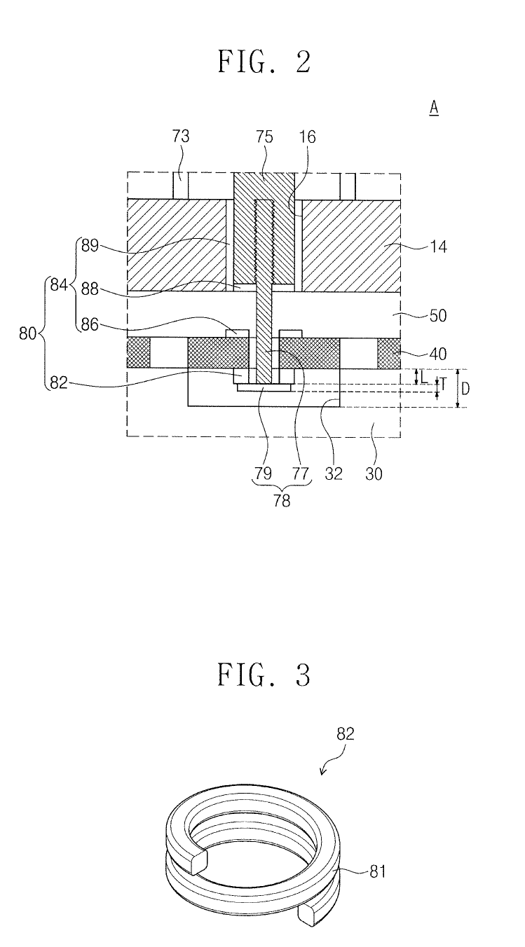

FIG. 2 shows an example of the power feed 78 and the connection part 80 in section A of FIG. 1.

Referring to FIG. 2, the power feed 78 may be provided within the inner waveguide 75 inserted into the first upper cavity 16. The power feed 78 may extend from the inner waveguide 75 via the dielectric plate 50 and the antenna 40 to a central groove 32 of the dielectric window 30. For example, the power feed 78 may include metal (e.g., Cu, Ni, or Au). The power feed 78 may have a screw shape. In an embodiment, the power feed 78 may include a screw rod 77 and a screw head 79. The screw rod 77 may couple the inner waveguide 75 to the screw head 79. The screw rod 77 may pass through a center of each of the dielectric plate 50 and the antenna 40. The screw head 79 may be disposed in the central groove 32 of the dielectric window 30. The screw head 79 may be connected to a lower portion of the screw rod 77.

The connection part 80 may be disposed around the screw rod 77 between the inner waveguide 75 and the screw head 79. The connection part 80 may couple the screw head 79 to the antenna 40. The connection part 80 may provide the antenna 40 with the microwave power output 72 of the power feed 78. The connection part 80 may seal between the upper housing 14 and the inner waveguide 75. In such a configuration, the connection part 80 may prevent and/or minimize gas inflow and/or air inflow from outside the upper housing 14. In an embodiment, the connection part 80 may include a lower connection part 82 and an upper connection part 84. The lower connection part 82 may be disposed between the antenna 40 and the screw head 79 around the screw rod 77. The lower connection part 82 may electrically connect the screw head 79 with the antenna 40.

When the microwave power output 72 is provided through the screw rod 77 to the antenna 40, the microwave power output 72 may heat up the screw rod 77. When the screw rod 77 is heated up, the screw rod 77 may increase in length. For example, the screw rod 77 may expand and/or contract in a longitudinal direction. The screw head 79 and the antenna 40 may have a variable distance therebetween. The central groove 32 of the dielectric window 30 may have a floor depth D equal to or greater than a sum of a thickness T of the screw head 79 and a maximum length L between the screw head 79 and the antenna 40. The central groove 32 may prevent the dielectric window 30 from being deformed due to the expansion of the screw rod 77 in the longitudinal direction.

FIG. 3 shows an example of the lower connection part 82 of FIG. 2.

Referring to FIGS. 2 and 3, the lower connection part 82 may include a cup spring washer 81. The cup spring washer 81 may turn at least once. The cup spring washer 81 may stretch in the longitudinal direction of the screw rod 77. The cup spring washer 81 may accordingly couple the screw head 79 to the antenna 40, regardless of the expansion and/or contraction of the screw rod 77 in the longitudinal direction.

Referring back to FIG. 2, the upper connection part 84 may be disposed around the screw rod 77 between the inner waveguide 75 and the antenna 40. The upper connection part 84 may include a gasket. The upper connection part 84 may seal between the inner waveguide 75 and an inner wall of the upper housing 14 in the first upper cavity 16. The upper connection part 84 may also seal between a bottom surface of the inner waveguide 75 and a top surface of the dielectric plate 50. The upper connection part 84 may further seal between a bottom surface of the dielectric plate 50 and a top surface of the antenna 40. In an embodiment, the upper connection part 84 may include a first sealing member 86, a second sealing member 88, and a third sealing member 89.

The first sealing member 86 may be disposed between the antenna 40 and the dielectric plate 50. The first sealing member 86 may provide a seal between the bottom surface of the dielectric plate 50 and the top surface of the antenna 40 around the screw rod 77.

The second sealing member 88 may be disposed within the first upper cavity 16 on the first sealing member 86. The second sealing member 88 may be disposed between the dielectric plate 50 and the inner waveguide 75. The second sealing member 88 may provide a seal between the bottom surface of the inner waveguide 75 and the top surface of the dielectric plate 50 around the screw rod 77.

The third sealing member 89 may surround the second sealing member 88 and the inner waveguide 75 within the first upper cavity 16. The third sealing member 8-9 may provide a seal between an outer wall of the inner waveguide 75 and the inner wall of the upper housing 14 in the first upper cavity 16. The second sealing member 88 and third sealing member 89 may suppress air inflow into the upper housing 14 from the outer waveguide 73. For example, the second sealing member 88 and third sealing member 89 may prevent inflow of a second gas (see 26 of FIG. 1) from outside the upper housing 14.

Referring back to FIG. 1, independently of the power supply 70, the second pump 90 may be associated with the upper housing 14. For example, the second pump 90 may be connected with a second upper cavity 18 of the upper housing 14. The second upper cavity 18 may partially expose the dielectric plate 50. The second pump 90 may pump a second gas 26 on or over the dielectric window 30. The second pump 90 may pump and/or exhaust the second gas 26 through the second upper cavity 18 and the gap 28. Since the upper housing 14 is hermetically sealed with the upper connection part 84, the pumping of the second pump 90 may rigidly hold or adsorb the dielectric window 30, the antenna 40, and the dielectric plate 50 onto the inside wall of the upper housing 14. The dielectric window 30, the antenna 40, and the dielectric plate 50 may be cooled down with coolant (not shown) flowing through a coolant hole 17 of the upper housing 14. When the second pump 90 does not pump the second gas 26, the dielectric window 30 may deform convexly toward the lower housing 12. In some embodiments, since the second pump 90 pumps the second gas 26, the dielectric window 30 may be rigidly held or adsorbed onto the inside wall of the upper housing 14, with the result that the dielectric window 30 may be prevented from being deformed.

The second pump 90 has a pumping pressure lower than the atmosphere pressure. When the second pump 90 pumps the second gas 26, the second gas 26 may have a pressure ranging from about 100 Torr to about 400 Torr. For example, the second pump 90 may include a venturi pump. In an embodiment, the second pump 90 may include an air supply 92, an air exhaust 94, and a venturi tube 96. The air supply 92 may provide air 99 under a pressure greater than atmospheric pressure. The air exhaust 94 may discharge the air 99. The venturi tube 96 may couple the air supply 92 to the air exhaust 94. The venturi tube 96 may have an air nozzle 98. The air nozzle 98 may be engaged with the second upper cavity 18. The air nozzle 98 may use the air 99 to pump the second gas 26 in the second upper cavity 18. When the air 99 expands in the air nozzle 98, the second gas 26 may be pumped along with the air 99 into the air nozzle 98. The second gas 26 in the upper housing 14 may then have a pressure ranging from about 100 Torr to about 400 Torr lower than atmospheric pressure.

It will be described below a method of manufacturing a semiconductor device using the plasma processing apparatus 100 configured as described above.

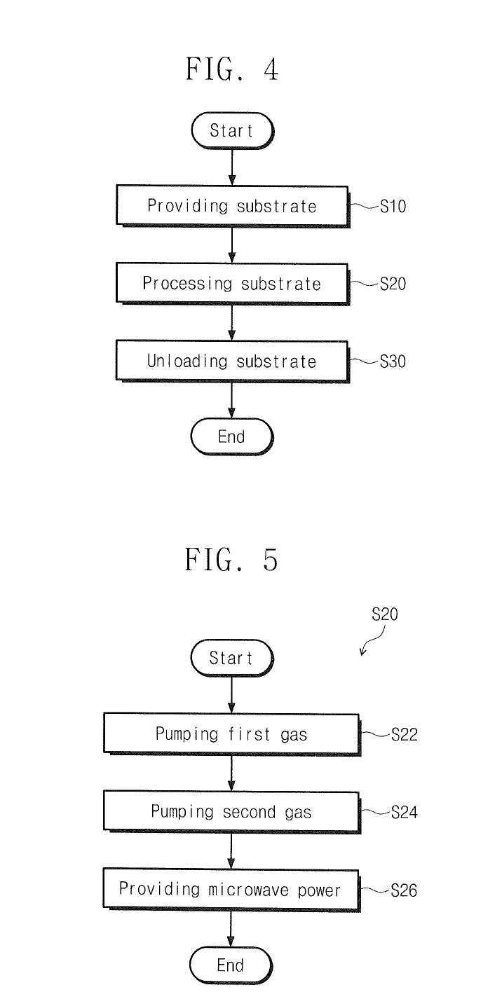

FIG. 4 shows a method of manufacturing a semiconductor device according to exemplary embodiments of inventive concepts.

Referring to FIG. 4, according to exemplary embodiments of inventive concepts, a method of manufacturing a semiconductor device may include a step S10 of providing the substrate W into the chamber 10, a step S20 of processing the substrate W, and a step S30 of unloading the substrate W.

When the lower housing 12 is separated from the upper housing 14, a robot arm (not shown) may provide the substrate W onto the chuck 20 installed in the lower housing 12 (S10).

When the lower housing 12 is combined with the upper housing 14, a controller (not shown) may use the plasma 24 to process the substrate W (S20).

FIG. 5 shows an example of the step S20 of processing the substrate W of FIG. 4.

Referring to FIG. 5, the step S20 of processing the substrate W may include a step S22 of pumping the first gas 22, a step S24 of pumping the second gas 26, and a step S26 of providing the microwave power output 72.

The first pump 60 may pump the first gas 22 (S22). The first gas 22 may include a purge gas (e.g. N₂), an inert gas (e.g., Ar or He), or a reaction gas (e.g., H₂, O₂, CH₄, SF₆, SiH₄, or NH₃). The first gas 22 may be provided into the chamber 10 from a gas supply (not shown). For example, the first gas 22 may have a pressure ranging from about 1 mTorr to about 100 mTorr in the lower housing 12.

The second pump 90 may pump the second gas 26 (S24). The second gas 26 may be pumped to have a pressure ranging from about 100 Torr to about 400 Torr in the upper housing 14. The second gas 26 may be substantially different than the first gas 22. The second gas 26 may be the air.

The power supply 70 may provide the antenna 40 with the microwave power output 72 to generate the plasma 24 on the substrate W (S26). Independently of the outer waveguide 73, the second pump 90 may pump the second gas 26. Under atmospheric pressure, the outer waveguide 73 of the power supply 70 may transfer the microwave power output 72 to the inner waveguide 75. The microwave power output 72 may be delivered via air in the outer waveguide 73. When the outer waveguide 73 has atmospheric pressure larger than vacuum pressure, the microwave power output 72 may increase in transfer efficiency. When the microwave power output 72 is provided to the antenna 40, the plasma 24 may be generated on the substrate W. When the gas supply (not shown) provides the first gas 22 into the chamber 10, the first pump 60 may cause the first gas 22 to have a pressure ranging from about 1 mTorr to about 100 mTorr in the lower housing 12. The plasma 24 may process and/or work on the substrate W. For example, in some embodiments, when the first gas 22 is the reaction gas, the plasma 24 may etch the substrate W. In other embodiments, a thin layer may be deposited on the substrate W.

Referring back to FIG. 4, when an etching process and/or a thin-layer depositing process on the substrate W are complete, the robot arm (not shown) may operate such that the substrate W is unloaded from the chuck 20 to outside the lower housing 12 (S30). Before the substrate W is unloaded, the lower housing 12 may be separated from the upper housing 14.

In a plasma processing apparatus according to inventive concepts, a second gas above a window may be pumped to a pressure less than the atmosphere pressure such that the window may be rigidly held or adsorbed onto an upper inside wall of a chamber, and this mechanism may minimize and/or prevent deformation of the window. The second gas may be pumped independently of a power supply, and thus it may be possible to prevent power delivery loss of the power supply.

The exemplary embodiments have been described in the specification and drawings. Although specific terms are used herein, they are merely used for the purpose of describing inventive concepts rather than limiting technical meanings or scopes of inventive concepts disclosed in the claims. Therefore, it will be appreciated by a person of ordinary skill in the art that various modifications and equivalent embodiments can be made from inventive concepts. In conclusion, the authentic technical scope of inventive concepts to be protected shall be determined by the technical concepts of the accompanying claims.

What is claimed is:

1. A plasma processing apparatus, comprising:
a chamber comprising a lower housing and an upper housing on the lower housing;
a window in the upper housing;
an antenna for generating a plasma of a first gas, wherein the antenna is disposed on the window and in the upper housing;
a first pump for exhausting the first gas between the window and the lower housing, wherein the first pump is associated with the lower housing;
a power supply for providing a power output, wherein the power supply is connected to the antenna through a first cavity of the upper housing; and
a second pump for pumping a second gas between the window and the upper housing so as to hold the antenna and the window onto an inside wall of the upper housing, wherein the second pump is associated with a second cavity of the upper housing, wherein the second cavity is different than the first cavity, and wherein the second pump is associated independently of the power supply.

2. The plasma processing apparatus of claim 1, wherein the first pump comprises a dry pump, and wherein the second pump comprises a venturi pump that generates a pressure lower than atmospheric pressure.

3. The plasma processing apparatus of claim 2, wherein the second pump comprises:
an air supply providing air;
an air exhaust discharging the air; and
a venturi tube between the air exhaust and the air supply, wherein the venturi tube uses the air to pump the second gas into the air exhaust wherein the venturi tube has a venturi nozzle connected to the second cavity.

4. The plasma processing apparatus of claim 1, wherein the power supply comprises:
a power source;
a waveguide coupling the power source to the first cavity; and
a power feed over the window in the upper housing, wherein the power feed couples the waveguide to the antenna.

5. The plasma processing apparatus of claim 4, wherein the power feed comprises:
a screw head between the window and the antenna; and
a screw rod passing through the antenna, wherein the screw rod couples the waveguide to the screw head.

6. The plasma processing apparatus of claim 5, further comprising a connection part surrounding the screw rod and between the waveguide and the antenna,
wherein the connection part comprises:
a lower connection part between the antenna and the screw head; and
an upper connection part between the antenna and the waveguide.

7. The plasma processing apparatus of claim 6, wherein the lower connection part comprises a cup spring washer.

8. The plasma processing apparatus of claim 6, wherein the upper connection part comprises a gasket.

9. The plasma processing apparatus of claim 6, further comprising a dielectric plate on the antenna and in the upper housing,
wherein the upper connection part comprises:
a first sealing member between the antenna and the dielectric plate, wherein the first sealing member provides a seal between a bottom surface of the dielectric plate and a top surface of the antenna around the screw rod; and
a second sealing member between the dielectric plate and the waveguide, wherein the second sealing member provides a seal between a bottom surface of the waveguide and a top surface of the dielectric plate around the screw rod.

10. The plasma processing apparatus of claim 6, wherein the waveguide comprises:
an outer waveguide coupling the power source to the first cavity; and
an inner waveguide in the first cavity within the outer waveguide,
wherein the upper connection part further comprises a third sealing member surrounding the inner waveguide in the first cavity, and wherein the third sealing member provides a seal between an inner wall of the upper housing in the first cavity and an outer wall of the inner waveguide.

11. A plasma processing apparatus, comprising:
a chamber;
a window in the chamber;
an antenna for generating plasma, wherein the antenna is disposed on the window and in the chamber; and
a power supply for delivering power to the antenna, wherein the power supply comprises a power feed,
wherein the power feed passes through the antenna and extends to the window, and wherein the window has a central groove receiving an end of the power feed.

12. The plasma processing apparatus of claim 11, wherein the power feed comprises:
a rod passing through the antenna; and
a head connected to the rod and in the central groove.

13. The plasma processing apparatus of claim 12, wherein the central groove has a depth greater than a sum of a thickness of the head and a length of the rod between a top surface of the head and a bottom surface of the antenna.

14. The plasma processing apparatus of claim 12, further comprising a connection part around the rod between the head and the antenna, wherein the connection part couples the head to the antenna.

15. The plasma processing apparatus of claim 14, wherein the connection part comprises a cup spring washer.

16. A method of manufacturing a semiconductor device, the method comprising:
providing a substrate into a lower housing of a chamber; and
processing the substrate using a microwave power output provided through an antenna and a window that are in an upper housing on the lower housing,
wherein processing the substrate comprises:
pumping a first gas between the lower housing and the window;
pumping a second gas on the window and in the upper housing; and
generating a plasma of the first gas by providing the antenna with the microwave power output from a power supply,
wherein pumping the second gas comprises exhausting the second gas independently of the power supply.

17. The method of claim 16, wherein:
the first gas is pumped under a pressure ranging from 1 mTorr to 100 mTorr; and
the second gas is pumped under a pressure ranging from 100 Torr to 400 Torr.

18. The method of claim 17, wherein providing the microwave power output comprises delivering the microwave power output under atmospheric pressure greater than those of the first gas and second gas.

19. The method of claim 16, wherein:
the power supply provides the microwave power output through a first cavity of the upper housing; and
the second gas is pumped through a second cavity of the upper housing, wherein the second cavity different than the first cavity.
